(19) United States
(12) Patent Application Publication
(10) Pub. No.: US 2026/0293296 A1
(43) Pub. Date: Sep. 24, 2026

(54) INTEGRATED CIRCUIT DEVICE INCLUDING A POWER VIA AND METHOD OF MANUFACTURING INTEGRATED CIRCUIT DEVICE

(71) Applicant: SAMSUNG ELECTRONICS CO., LTD., Suwon-si (KR)

(72) Inventors: Junghoo SHIN, Suwon-si (KR); Jinnam KIM, Suwon-si (KR); Wookyung YOU, Suwon-si (KR); Sangcheol NA, Suwon-si (KR)

(73) Assignee: SAMSUNG ELECTRONICS CO., LTD., Suwon-si (KR)

(21) Appl. No.: 19/392,908

(22) Filed: Nov. 18, 2025

(30) Foreign Application Priority Data
Mar. 19, 2025 (KR) 10-2025-0035528

(51) Int. Cl. H10D 84/83; H10D 30/00; H10D 30/43; H10D 62/10; H10D 62/13; H10D 64/23; H10W 20/40; H10W 20/41; H10W 20/42; H10D 30/01; H10D 84/01

(52) U.S. Cl. CPC H10D 84/8312; H10D 30/43; H10D 30/502; H10D 62/121; H10D 62/151; H10D 64/256; H10D 84/832; H10W 20/42; H10W 20/427; H10W 20/435; H10W 20/498; H10D 30/014; H10D 30/0191; H10D 84/0149

(57) ABSTRACT

An integrated circuit includes: a cell transistor including: a nanosheet stack including nanosheets spaced apart from each other in a vertical direction; a gate electrode on the nanosheet stack and extending in a horizontal direction; and a first source/drain region connected to the nanosheet stack; a back contact beneath the cell transistor and connected to the first source/drain region; a first power via at a vertical level lower than that of the back contact; a front wiring structure on and connected to the cell transistor; and a back wiring structure beneath the first power via and connected to the cell transistor. The back wiring structure is configured such that connected to the first power via and the back contact. And a lower surface of the first power via does not overlap the back contact in the vertical direction and includes a recess.

### CROSS-REFERENCE TO RELATED APPLICATION

This application is based on and claims priority to Korean Patent Application No. 10-2025-0035528, filed on Mar. 19, 2025, in the Korean Intellectual Property Office, the disclosure of which is incorporated by reference herein in its entirety.

### BACKGROUND

### 1. Field

The present disclosure relates to an integrated circuit device and a method of manufacturing the integrated circuit device, and more particularly, to an integrated circuit device including a back-side power delivery network (BSPDN) structure having a wiring structure formed on the back surface of a cell transistor and a method of manufacturing the integrated circuit device.

### 2. Description of Related Art

Along with the development of electronic technologies, down-scaling of integrated circuit devices has rapidly progressed. Accordingly, research has been conducted into efficiently designing wiring structures to achieve high integration while ensuring the functions and operating speed required in an integrated circuit device. For example, a power distribution network (PDN) configured to supply power onto the back surface of a cell transistor may be provided to minimize routing congestion of an integrated circuit device and reduce the area of the integrated circuit device.

### SUMMARY

Provided is an integrated circuit device with improved electrical characteristics and a method of manufacturing the integrated circuit device.

According to an aspect of the disclosure, an integrated circuit device includes: a cell transistor including: a nanosheet stack including a plurality of nanosheets spaced apart from each other in a vertical direction; a gate electrode on the nanosheet stack and extending in a horizontal direction; and a first source/drain region connected to the nanosheet stack; a back contact beneath the cell transistor and connected to the first source/drain region; a first power via at a vertical level lower than that of the back contact; a front wiring structure on and connected to the cell transistor; and a back wiring structure beneath the first power via and connected to the cell transistor, wherein the back wiring structure is connected to the first power via and the back contact, and wherein a lower surface of the first power via does not overlap the back contact in the vertical direction and includes a recess.

According to an aspect of the disclosure, an integrated circuit device including: a plurality of cell transistors including: a plurality of nanosheet stacks each including a plurality of nanosheets spaced apart from each other in a vertical direction; a plurality of gate electrodes respectively on the plurality of nanosheet stacks and extending in a horizontal direction; and a plurality of source/drain regions each between gate electrodes from among the plurality of gate electrodes and connected to one or more of the plurality of nanosheet stacks; a plurality of back contacts beneath the plurality of cell transistors and connected to the plurality of source/drain regions; a plurality of power vias at a vertical level lower than that of the plurality of back contacts and connected to the plurality of back contacts; a plurality of back via contacts at a vertical level lower than that of the plurality of power vias and connected to the plurality of power vias; a front wiring structure on and connected to the plurality of cell transistors; and a back wiring structure on lower surfaces of the plurality of power vias and connected to the plurality of cell transistors, wherein the back wiring structure is connected to the plurality of back contacts, the plurality of power vias, and the plurality of back via contacts, and wherein a lower surface of a first power via not overlapping the plurality of back contacts in the vertical direction, among the plurality of power vias, includes a recess.

According to an aspect of the disclosure, an integrated circuit device including: a plurality of cell transistors including: a plurality of nanosheet stacks each including a plurality of nanosheets spaced apart from each other in a vertical direction; a plurality of gate electrodes respectively on the plurality of nanosheet stacks and extending in a horizontal direction; and a plurality of source/drain regions each between gate electrodes from among the plurality of gate electrodes and connected to one or more of the plurality of nanosheet stacks; an intermediate insulating layer beneath the plurality of cell transistors; a plurality of back contacts below the plurality of cell transistors and connected to a first source/drain region among the plurality of source/drain regions by passing through at least a portion of the intermediate insulating layer; a plurality of power vias connected to the plurality of back contacts and passing through at least a portion of the intermediate insulating layer at a vertical level lower than a vertical level of the plurality of back contacts; a plurality of back via contacts at a vertical level lower than that of the plurality of power vias and connected to the plurality of power vias; a plurality of front contacts on the plurality of cell transistors and connected to a second source/drain region among the plurality of source/drain regions; a plurality of gate contacts on the plurality of cell transistors and connected to the plurality of gate electrodes; a front wiring structure on an upper surface of each of the plurality of front contacts and the plurality of gate contacts, and connected to the plurality of cell transistors; and a back wiring structure on lower surfaces of the plurality of power vias and connected to the plurality of cell transistors, wherein the front wiring structure is connected to the plurality of front contacts and the plurality of gate contacts, wherein the back wiring structure is connected to the plurality of power vias and the plurality of back via contacts, and wherein a lower surface of a first power via not overlapping the plurality of back contacts in the vertical direction, among the plurality of power vias, includes a recess.

According to another aspect of the disclosure, a method of manufacturing an integrated circuit device includes: forming a plurality of cell transistors including a plurality of gate structures, a plurality of nanosheet stacks, and a plurality of source/drain regions on a substrate; forming a front wiring structure on the plurality of cell transistors; forming an intermediate insulating layer on lower surfaces of the plurality of cell transistors and forming a plurality of back contacts and a plurality of power vias passing through at least a portion of the intermediate insulating layer; and forming a back wiring structure on lower surfaces of the plurality of power vias, wherein the forming of the plurality of power vias includes forming a recess in the lower surfaces of the plurality of power vias.

The forming of the plurality of power vias may include forming a back hole passing through at least a portion of the intermediate insulating layer, filling the back hole with a conductive material, and forming a power via including the recess by removing a portion of the conductive material.

The removing of the portion of the conductive material may be performed by at least one of chemical mechanical polishing (CMP), dry etching, wet etching, and laser ablation.

The forming of the power via may include forming the recess in a first power via overlapping the plurality of back contacts in the vertical direction among the plurality of power vias.

The forming of the recess may include forming the recess in a tapered shape having a horizontal width gradually decreasing toward the plurality of cell transistors.

The method may further include, before the forming of the plurality of cell transistors, forming a placeholder extending downward in the vertical direction at a lower portion of a region in which the plurality of source/drain regions are to be placed.

The method may further include forming a plurality of back via contacts on lower surfaces of the plurality of power vias.

The forming of the plurality of back via contacts may be performed to form the plurality of back via contacts up to a vertical level higher than that of the recess.

The forming of the plurality of back via contacts may be performed such that the plurality of power vias and the plurality of back via contacts include a same constituent material.

The forming of the plurality of back via contacts may be performed such that the plurality of power vias and the plurality of back via contacts include different constituent materials.

The disclosure is not limited to the aspects and features mentioned above, and other aspects and features may be clearly understood by those of ordinary skill in the art from the description below.

### BRIEF DESCRIPTION OF THE DRAWINGS

The above and other aspects and features of the present disclosure will be more clearly understood from the following detailed description taken in conjunction with the accompanying drawings, in which:

FIG. 1 is a schematic diagram illustrating an integrated circuit device according to an embodiment;

FIG. 2 is a cross-sectional view taken along line X-X' of FIG. 1;

FIG. 3 is an enlarged diagram of region A of FIG. 2;

FIG. 4 is a cross-sectional view illustrating an integrated circuit device according to an embodiment;

FIGS. 5, 6A, 6B, 7A, 7B, 8A, 8B, 9A, 9B, 10A, 10B, and 11 to 19 are cross-sectional views illustrating, in a process order, a method of manufacturing the integrated circuit device shown in FIGS. 1 to 3; and

FIGS. 20 to 24 are cross-sectional views illustrating, in a process order, a method of manufacturing the integrated circuit device shown in FIG. 4, according to an embodiment.

### DETAILED DESCRIPTION

Hereinafter, one or more embodiments are described in detail with reference to the accompanying drawings. Like reference numerals in the drawings denote like elements, and thus their repetitive description will be omitted. In the drawings, the thicknesses or sizes of layers are exaggerated for convenience and clarity of description, and accordingly, may somewhat different from actual shapes and ratios.

Herein, the terms, e.g., "beneath", "below", "under", "on", "above", and the like, indicating spatial positions are only for easiness of understanding to describe a relative position relationship between elements shown in the drawings and do not have any intention to limit the present disclosure. The terms for spatial relative positions intend to include changes according to a direction of a semiconductor device in addition to a direction described in the drawings. That is, a semiconductor device may be oriented in various directions when used (or manufactured), and even in these cases, the terms of positions used in the specification may be understood by those of ordinary skill in the art.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

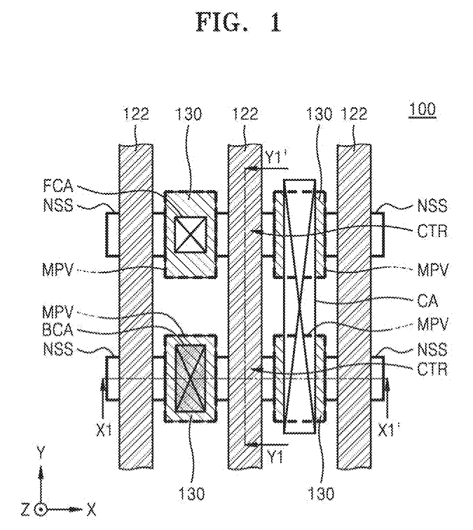

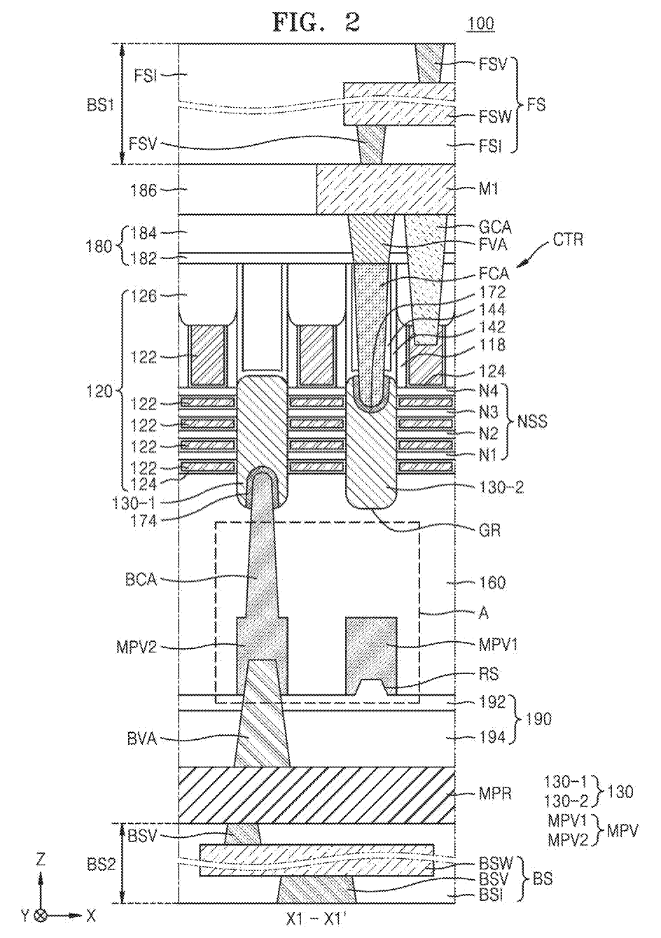

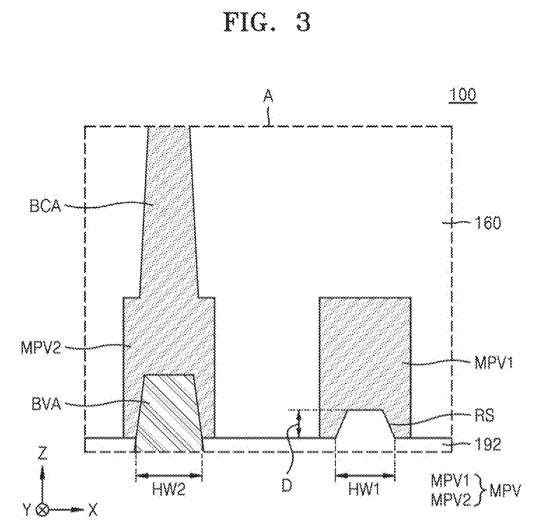

FIG. 1 is a schematic layout diagram illustrating an integrated circuit device 100 according to an embodiment. FIG. 2 is a cross-sectional view taken along line X-X' of FIG. 1. FIG. 3 is an enlarged diagram of region A of FIG. 2.

Referring to FIGS. 1 to 3, the integrated circuit device 100 may include a plurality of cell transistors CTR disposed at a first vertical level, a front wiring structure FS disposed at a second vertical level higher than the first vertical level and electrically connected to the plurality of cell transistors CTR, and a back wiring structure BS disposed at a third vertical level lower than the first vertical level and electrically connected to the plurality of cell transistors CTR.

In the integrated circuit device 100, a plurality of gate structures 120, a plurality of nanosheet stacks NSS including nanosheets (e.g., nanosheets N1, N2, N3, and N4) in a stacked arrangement, and a plurality of source/drain regions 130 may constitute a cell transistor CTR. Each of the plurality of cell transistors CTR may constitute various types of logic cells included in a logic circuit. In an embodiment, the integrated circuit device 100 may include a logic cell including a multi-bridge channel field-effect transistor (MBCFET) device. However, the present disclosure is not limited thereto, and the integrated circuit device 100 may include a planar field-effect transistor (FET) device, a gate-all-around-type FET device, a fin-type FET (finFET) device, a two-dimensional material-based FET device, such as a molybdenum disulfide (MoS₂) semiconductor gate electrode, and/or the like.

The integrated circuit device 100 may include an active region extending in a first horizontal direction (the X direction). The active region may be a p-type metal-oxide-semiconductor (PMOS) transistor region and/or an n-type metal-oxide-semiconductor (NMOS) transistor region. For example, the plurality of cell transistors CTR disposed in the active region may include a PMOS transistor or an NMOS transistor.

The plurality of cell transistors CTR may be spaced apart from each other in the first horizontal direction (the X direction) and a second horizontal direction (the Y direction). The plurality of cell transistors CTR may include the plurality of nanosheet stacks NSS, wherein the nanosheets of each nanosheet stack NSS are spaced apart from each other in the vertical direction (the Z direction), the plurality of gate structures 120 extending in the second horizontal direction (the Y direction) while at least partially surrounding the plurality of nanosheet stacks NSS, and the plurality of source/drain regions 130 disposed one by one at both sides of the plurality of gate structures 120 (e.g., disposed at both sides of each gate structure 120).

In the specification, a direction parallel to the main surface of the cell transistor CTR is defined as a horizontal direction (the X direction and/or the Y direction), and a direction perpendicular to the horizontal direction (the X direction and/or the Y direction) is defined as the vertical direction (the Z direction).

For convenience of description, a source/drain region 130 overlapping a back contact BCA in the vertical direction (the Z direction) may be referred to as a first source/drain region 130-1, and a source/drain region 130 not overlapping the back contact BCA in the vertical direction (the Z direction) may be referred to as a second source/drain region 130-2.

In an embodiment, each of the plurality of nanosheet stacks NSS may include a group IV semiconductor, such as silicon (Si) or germanium (Ge), a group IV-IV compound semiconductor, such as SiGe or silicon carbide (SiC), or a group III-V compound semiconductor, such as gallium arsenide (GaAs), indium arsenide (InAs), or indium phosphide (InP).

In an embodiment, the plurality of gate structures 120 may extend in the second horizontal direction (the Y direction) so as to at least partially surround the plurality of nanosheet stacks NSS and may be spaced apart from each other in the first horizontal direction (the X direction).

In an embodiment, each of the plurality of gate structures 120 may include a gate electrode 122, a gate insulating layer 124, and a gate capping layer 126. For example, the gate electrode 122 may extend in the second horizontal direction (the Y direction) so as to surround the plurality of nanosheet stacks NSS, and the gate insulating layer 124 may be disposed between the gate electrode 122 and each nanosheet stacks NSS. The gate capping layer 126 may extend in the second horizontal direction (the Y direction) on the upper surface of the gate electrode 122.

In an embodiment, the gate electrode 122 may include doped polysilicon, a metal, conductive metal nitride, conductive metal carbide, conductive metal silicide, or a combination thereof. For example, the gate electrode 122 may include aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum nitride (TiAlN), tantalum carbonitride (TaCN), tantalum carbide (TaC), tantalum silicon nitride (TaSiN), or a combination thereof but the disclosure is not limited thereto. In an embodiment, the gate electrode 122 may include a work function metal-containing layer and a gap-fill metal layer. The work function metal-containing layer may include at least one metal selected from among Ti, W, ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). the gap-fill metal layer may include a W layer or an Al layer. In an embodiment, the gate electrode 122 may include a stacked structure of titanium aluminum carbide (TiAlC)/TiN/W, a stacked structure of TiN/TaN/TiAlC/TiN/W, or a stacked structure of TiN/TaN/TiN/TiAlC/TiN/W but the disclosure is not limited thereto.

In an embodiment, the gate insulating layer 124 may include a silicon oxide layer, a silicon oxynitride (SiON) layer, a high dielectric layer having a dielectric constant higher than that of the silicon oxide layer, or a combination thereof. The high dielectric layer may include metal oxide or metal oxynitride. For example, the high dielectric layer usable as the gate insulating layer 124 may include hafnium dioxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO₂), alumina (Al₂O₃), or a combination thereof but the disclosure is not limited thereto.

An insulating spacer 118 may be further disposed on the sidewall of the gate electrode 122. The insulating spacer 118 may extend in the second horizontal direction (the Y direction) on the sidewall of the gate electrode 122.

A plurality of gate capping layers 126 may be disposed on the insulating spacer 118 and the gate electrode 122. The plurality of gate capping layers 126 may cover the upper surface of the insulating spacer 118 and the upper surface of the gate electrode 122. The plurality of gate capping layers 126 may include silicon dioxide (SiO₂), silicon nitride (Si₃N₄), SiON, silicon carbonitride (SiCN), silicon oxycarbonitride (SiOCN), or a combination thereof.

The source/drain region 130 may be formed on the sidewall of a gate structure 120. The source/drain region 130 may be connected to end portions of a nanosheet stack NSS. The source/drain region 130 may have an upper surface at a vertical level higher than that of the upper surface of the plurality of nanosheet stacks NSS. At least some of the plurality of source/drain regions 130 may be connected to a front contact FCA, and at least some of the remaining some of the plurality of source/drain regions 130 may be electrically connected to the back contact BCA.

In an embodiment, the source/drain region 130 may include a doped SiGe layer, a doped Ge layer, a doped SiC layer, or a doped indium gallium arsenide (InGaAs) layer, but the present disclosure is not limited thereto. In an embodiment, the source/drain region 130 may include a plurality of semiconductor layers having different compositions. For example, the source/drain region 130 may include a lower semiconductor layer, an upper semiconductor layer, and a capping semiconductor layer that are sequentially stacked. For example, each of the lower semiconductor layer, the upper semiconductor layer, and the capping semiconductor layer may include SiC with a different content of Si and carbon (C).

The cell transistor CTR may be an NMOS transistor or a PMOS transistor according to the conductive type of the plurality of nanosheet stacks NSS and/or the conductive type of the source/drain region 130.

An insulating liner 142 covering the upper surface of the source/drain region 130 may be disposed between gate structures 120. The insulating liner 142 may include SiO₂ or SiON.

An inter-gate insulating layer 144 may be disposed on the insulating liner 142. The inter-gate insulating layer 144 may include SiO₂ or SiON.

The front contact FCA may be disposed on the source/drain region 130 by passing through the inter-gate insulating layer 144. A front via contact FVA may be disposed on the front contact FCA. In an embodiment, the front contact FCA is electrically connected to the source/drain region 130 (e.g., the second source/drain region 130-2), and the front contact FCA and the front via contact FVA may be formed in a stacked structure such that the front via contact FVA is disposed on the front contact FCA. In an embodiment, the upper surface of the front contact FCA may be coplanar with the upper surfaces of a plurality of gate capping layers 126, and the lower surface of the front via contact FVA.

An upper insulating structure 180 may be disposed on the inter-gate insulating layer 144 and the plurality of gate capping layers 126. The upper insulating structure 180 may include an upper etch-stop layer 182 and an upper insulating layer 184 disposed on the upper etch-stop layer 182. The front via contact FVA described above may be formed by passing through the upper insulating structure 180.

A gate contact GCA may be disposed on the gate electrode 122 by passing through the inter-gate insulating layer 144 and the upper insulating structure 180. The upper surface of the front contact FCA may be coplanar with the upper surface of the inter-gate insulating layer 144 and the lower surface of the upper insulating structure 180. In an embodiment, the upper surface of the gate contact GCA may be at the same vertical level as that of the upper surface of the front via contact FVA. The gate contact GCA may be electrically connected to the gate electrode 122 and a plurality of upper wiring layers M1.

Each of the front contact FCA and the gate contact GCA may include a contact plug including Mo, Cu, W, Co, Ru, manganese (Mn), Ti, Ta, Al, a combination thereof, or an alloy thereof. In an embodiment, each of the front contact FCA and the gate contact GCA may further include a conductive barrier pattern surrounding the contact plug. The conductive barrier pattern may include a metal or metal nitride. For example, the conductive barrier pattern may include Ti, Ta, W, TiN, TaN, WN, tungsten carbonitride (WCN), titanium silicon nitride (TiSiN), TaSiN, tungsten silicon nitride (WSiN), or a combination thereof but the disclosure is not limited thereto.

An interlayer insulating layer 186 may be disposed on the upper insulating structure 180. The interlayer insulating layer 186 may cover the upper surface of the upper insulating structure 180. The plurality of upper wiring layers M1 passing through the interlayer insulating layer 186 may be disposed inside the interlayer insulating layer 186. An upper wiring layer M1 may be electrically connected to the front contact FCA, the front via contact FVA, and/or the gate contact GCA. For example, the upper wiring layer M1 may include Mo, Cu, W, Co, Ru, Mn, Ti, Ta, Al, a combination thereof, or an alloy thereof but the disclosure is not limited thereto.

The upper etch-stop layer 182 may include SiC, silicon nitride (SiN), SiCN, silicon oxycarbide (SiOC), aluminum nitride (AlN), aluminum oxynitride (AlON), aluminum oxide (AlO), aluminum oxycarbide (AlOC), or a combination thereof. The upper insulating layer 184 and the interlayer insulating layer 186 may include an oxide layer, a nitride layer, a low dielectric layer having a dielectric constant of about 2.2 to about 2.4, or a combination thereof. For example, the upper insulating layer 184 may include a tetraethylorthosilicate (TEOS) layer, a high density plasma (HDP) oxide layer, a boro-phospho-silicate glass (BPSG) layer, a flowable chemical vapor deposition (FCVD) oxide layer, an SiON layer, an SiN layer, an SiOC layer, a hydrogenated oxidized silicon carbon (SiCOH) layer, or a combination thereof but the disclosure is not limited thereto.

A first back-end of line (BEOL) structure BS1 may be disposed on the interlayer insulating layer 186. The first BEOL structure BS1 may be referred to as the front wiring structure FS. The front wiring structure FS may be electrically connected to the cell transistor CTR. The front wiring structure FS may include a front via FSV, a front wiring layer FSW, and a front insulating layer FSI. In an embodiment, the front wiring layer FSW may include a wiring pattern disposed at one vertical level or wiring patterns disposed at two or more vertical levels.

In an embodiment, the front insulating layer FSI may include an oxide layer, a nitride layer, a low dielectric layer having a dielectric constant of about 2.2 to about 2.4, or a combination thereof. The front wiring layer FSW may be electrically connected to the front contact FCA and the gate contact GCA. The front via FSV may be electrically connected to the front wiring layer FSW, and the sidewalls of the front wiring layer FSW and the front via FSV may be surrounded by the front insulating layer FSI.

An intermediate insulating layer 160 may extend onto a lower surface (or a bottom surface) of the cell transistor CTR (e.g., the bottom surface of the gate structure 120 and/or the bottom surface of the source/drain region 130). The intermediate insulating layer 160 may include SiO₂, Si₃N₄, SiON, SiCN, SiOCN, or a combination thereof.

The back contact BCA may be electrically connected to the source/drain region 130 by passing through the intermediate insulating layer 160. The back contact BCA may extend to a vertical level higher than the bottom surface of the source/drain region 130 so as to increase the contact area between the back contact BCA and the source/drain region 130.

In an embodiment, the back contact BCA may include only a metal plug including a single metal. In another embodiment, the back contact BCA may include the metal plug and a conductive barrier layer surrounding the metal plug. The metal plug may include Mo, W, Co, Ru, Mn, Ti, Ta, Al, Cu, a combination thereof, or an alloy thereof but the disclosure is not limited thereto. The conductive barrier layer may include a metal or conductive metal nitride. For example, the conductive barrier layer may include Ti, Ta, W, TiN, TaN, WN, WCN, TiSiN, TaSiN, WSiN, or a combination thereof but the disclosure is not limited thereto.

In an embodiment, a back metal silicide layer 174 may be between the source/drain region 130 and the back contact BCA. The back metal silicide layer 174 may include a metal including Ti, W, Ru, Nb, Mo, Hf, Ni, Co, Pt, Yb, Tb, Dy, Er, or Pd. For example, the back metal silicide layer 174 may include titanium silicide (TiSi) but the disclosure is not limited thereto.

A power via MPV may be disposed on the lower surface of the back contact BCA. One surface of the power via MPV may have a recess RS. In an embodiment, the lower surface of the power via MPV may have the recess RS. That is, one of the two surfaces of the power via MPV spaced apart from each other, which is farther from the first BEOL structure BS1 in the vertical direction (the Z direction), may have the recess RS. The recess RS may be defined as a groove and/or a dent portion formed in one surface of the power via MPV. Therefore, the one surface of the power via MPV may have a concave shape. In an embodiment, the lower surface of the power via MPV may have a concave shape. In a plan view, the recess RS may be adjacent to the center of the power via MPV.

For convenience of description, a power via MPV not overlapping the back contact BCA in the vertical direction (the Z direction) may be referred to as a first power via MPV1, and a power via MPV overlapping the back contact BCA in the vertical direction (the Z direction) may be referred to as a second power via MPV2. The first power via MPV1 may also include a recess RS. In an example, lower surfaces of the plurality of power vias MPVs including the first and second power vias MPV1 and MPV2 may be at a same vertical level.

The power via MPV may extend in the horizontal direction (the X direction and/or the Y direction) on the back contact BCA. In a plan view, the power via MPV may have a plurality of line shapes spaced apart from each other. In an embodiment, the second power via MPV2 may be integrally formed with the back contact BCA. In another embodiment, the second power via MPV2 may be separately formed from the back contact BCA.

In an embodiment, the first power via MPV1 not overlapping the back contact BCA in the vertical direction (the Z direction) may include the recess RS. In addition, the first power via MPV1 not overlapping a back via contact BVA in the vertical direction (the Z direction) may include the recess RS. On a vertical cross-section, the recess RS may have a tapered shape having a horizontal width gradually decreasing toward the cell transistor CTR.

A first horizontal width HW1 that is the horizontal width of the recess RS may be about 5 nm to about 20 nm. In addition, a vertical depth D of the recess RS may be about 5 nm to about 20 nm. When the power via MPV has the recess RS, the contact area between the power via MPV and the back via contact BVA may increase. Therefore, the electrical resistance between the power via MPV and the back via contact BVA may decrease, thereby improving the electrical characteristics of the integrated circuit device 100.

A lower insulating structure 190 covering the lower surface of each of the intermediate insulating layer 160 and the power via MPV may be disposed on the lower surfaces of the intermediate insulating layer 160 and the power via MPV. The lower insulating structure 190 may include a lower etch-stop layer 192 and a lower insulating layer 194.

The lower etch-stop layer 192 may include SiC, SiN, SiCN, SiOC, AlN, AlON, AlO, AlOC, or a combination thereof. The lower insulating layer 194 may include an oxide layer, a nitride layer, a low dielectric layer having a dielectric constant of about 2.2 to about 2.4, or a combination thereof. For example, the lower insulating layer 194 may include a TEOS layer, an HDP oxide layer, a BPSG layer, an FCVD oxide layer, an SiON layer, an SiN layer, an SiOC layer, an SiCOH layer, or a combination thereof but the disclosure is not limited thereto.

The back via contact BVA may be electrically connected to the power via MPV by passing through the lower insulating structure 190. The upper surface of the back via contact BVA may have a vertical level higher than that of the upper surface of the recess RS of the first power via MPV1. In addition, at the same vertical level, a second horizontal width HW2 that is the horizontal width of the back via contact BVA may be greater than the first horizontal width HW1 that is the horizontal width of the recess RS of the first power via MPV1.

In an embodiment, the power via MPV and the back via contact BVA may include different materials. In another embodiment, the power via MPV and the back via contact BVA may include the same material.

A back power rail MPR may be disposed on the lower surface of the back via contact BVA. The back power rail MPR may be electrically connected to the back via contact BVA.

The back wiring structure BS may be disposed on the bottom surface of the cell transistor CTR (e.g., the lower surface of the power via MPV or the lower surface of the back power rail MPR. The back wiring structure BS may include a power delivery network configured to apply a power source voltage and a ground voltage to the cell transistor CTR. The back wiring structure BS may include a back via BSV, a back wiring layer BSW, and a back insulating layer BSI.

In an embodiment, the back contact BCA, the back via BSV, and/or the back wiring layer BSW may include at least one of W, Co, Mo, Ni, Ru, Cu, Al, silicide thereof, and an alloy thereof.

In an embodiment, a conductive barrier layer surrounding the upper surface and the sidewall of each of the back contact BCA, the power via MPV, the back via contact BVA, the back power rail MPR, and/or the back wiring layer BSW may be further formed, and the conductive barrier layer may include at least one of Ru, Ti, TiN, Ta, TaN, W, TiSiN, TiSi, and tungsten silicide (WSi).

Along with the progress of scale-down of the integrated circuit device 100, a device structure in which a front wiring structure for signal transmission is disposed on the upper surface of the cell transistor CTR and a back wiring structure for applying the power source voltage and the ground voltage is disposed on the bottom surface of the cell transistor CTR has been proposed. When a second BEOL structure BS2 is formed, the recess RS may be formed in the power via MPV to increase the contact area between the power via MPV and the back via contact BVA. Therefore, the electrical characteristics between the power via MPV and the back via contact BVA may be improved. Therefore, the electrical characteristics of the integrated circuit device 100 may be improved.

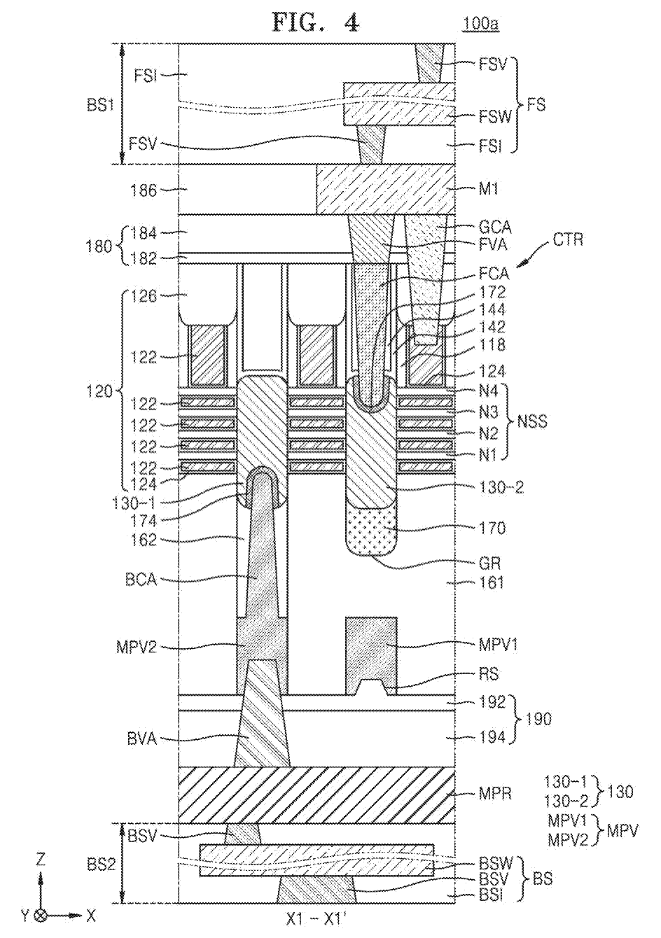

FIG. 4 is a cross-sectional view illustrating an integrated circuit device 100a according to an embodiment. FIG. 4 is a cross-sectional view corresponding to the line X-X' of FIG. 1. A description of FIG. 4 is made with reference to FIGS. 1 to 3 together.

The integrated circuit device 100a of FIG. 4 may be substantially the same as the integrated circuit device 100 of FIGS. 1 to 3 except that the integrated circuit device 100a includes a placeholder 170. Therefore, the placeholder 170 is mainly described herein.

Referring to FIG. 4, the placeholder 170 may be disposed on the bottom surface of at least one source/drain region 130 (e.g., the second source/drain region 130-2) among the plurality of source/drain regions 130. For example, the placeholder 170 may include SiGe and/or Si₃N₄.

The placeholder 170 may not overlap the back contact BCA in the vertical direction (the Z direction). In a plan view, the placeholder 170 may be spaced apart from the back contact BCA in the horizontal direction (the X direction and/or the Y direction). The placeholder 170 may extend downward from the bottom surface of the source/drain region 130 in the vertical direction (the Z direction). The placeholder 170 may overlap the first power via MPV1 in the vertical direction (the Z direction).

A second intermediate insulating layer 162 may be disposed on the bottom surface of the first source/drain region 130-1 overlapping the back contact BCA in the vertical direction (the Z direction), and a first intermediate insulating layer 161 may be disposed on the bottom surface of the second source/drain region 130-2 not overlapping the back contact BCA in the vertical direction (the Z direction). The back contact BCA may be electrically connected to the source/drain region 130 by passing through the second intermediate insulating layer 162.

That is, the placeholder 170 and the first power via MPV1 not overlapping the back contact BCA in the vertical direction (the Z direction) may be surrounded by the first intermediate insulating layer 161, and the back contact BCA and the second power via MPV2 may be surrounded by the second intermediate insulating layer 162.

The first intermediate insulating layer 161 and the second intermediate insulating layer 162 may include SiO₂, Si₃N₄, SiON, SiCN, SiOCN, or a combination thereof.

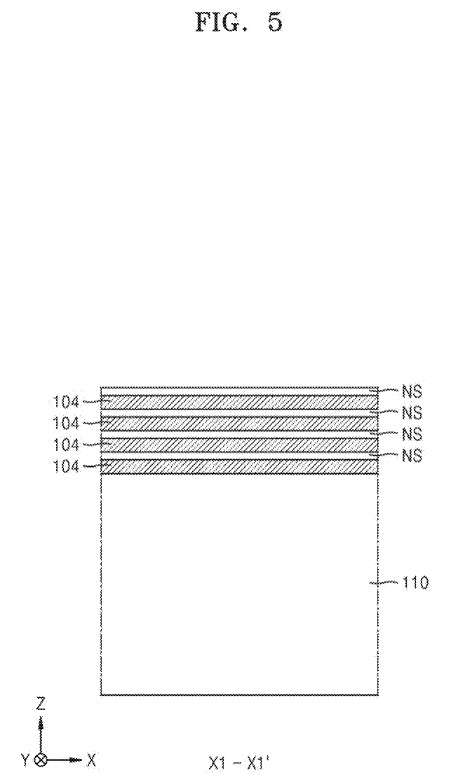

FIGS. 5 to 19 are cross-sectional views illustrating, in a process order, a method of manufacturing the integrated circuit device 100 shown in FIGS. 1 to 3, wherein FIGS. 5, 6A, 7A, 8A, 9A, 10A, 11, 12, 13, 14, 15, 16, 17, 18, and 19 are cross-sectional views illustrating, in a process order, a cross-sectional structure of a portion corresponding to the cross-section taken along the line X1-X1' of FIGS. 1, and 6B, 7B, 8B, 9B, and 10B, are cross-sectional views illustrating, in a process order, a cross-sectional structure of a portion corresponding to the cross-section taken along line Y1-Y1' of FIG. 1. In FIGS. 5 to 19, like reference numerals in FIGS. 1 to 3 denote like members, and thus, a detailed description thereof is omitted herein.

Referring to FIG. 5, a stacked structure may be formed by alternately and sequentially stacking a plurality of sacrificial semiconductor layers 104 and a plurality of semiconductor layers NS on the upper surface of a substrate 110. In an embodiment, the plurality of sacrificial semiconductor layers 104 and the plurality of semiconductor layers NS may be formed by an epitaxy process. In the stacked structure, the plurality of sacrificial semiconductor layers 104 and the plurality of semiconductor layers NS may include semiconductor materials having different etch selectivities.

In an embodiment, the epitaxy process may include a vapor-phase epitaxy (VPE) process, a chemical vapor deposition (CVD) process, such as an ultra-high vacuum chemical vapor deposition (UHV-CVD), a molecular beam epitaxy process, or a combination thereof. In the epitaxy process, a liquid or vapor precursor may be used as a precursor required to form the plurality of sacrificial semiconductor layers 104 and the plurality of semiconductor layers NS.

For example, each of the plurality of sacrificial semiconductor layers 104 and the plurality of semiconductor layers NS may include a monocrystalline layer of a group IV semiconductor, a group IV-IV compound semiconductor, or a group III-V compound semiconductor. In an embodiment, the plurality of sacrificial semiconductor layers 104 may include SiGe, and the plurality of semiconductor layers NS may include Si. An SiGe layer constituting a sacrificial semiconductor layer 104 may have a certain Ge content ratio selected within the range of about 5 atom% to about 50 atom%, e.g., about 10 atom% to about 40 atom%. In an embodiment, each of the plurality of sacrificial semiconductor layers 104 may include an SiGe layer, and the Ge content ratio in each of the plurality of sacrificial semiconductor layers 104 may be identical.

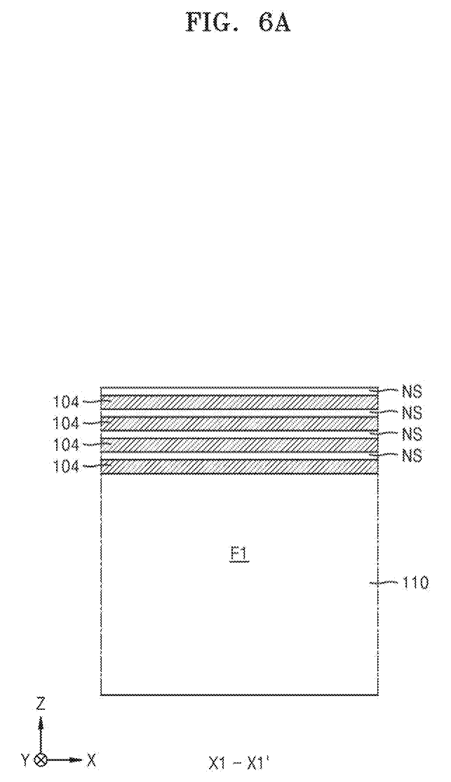

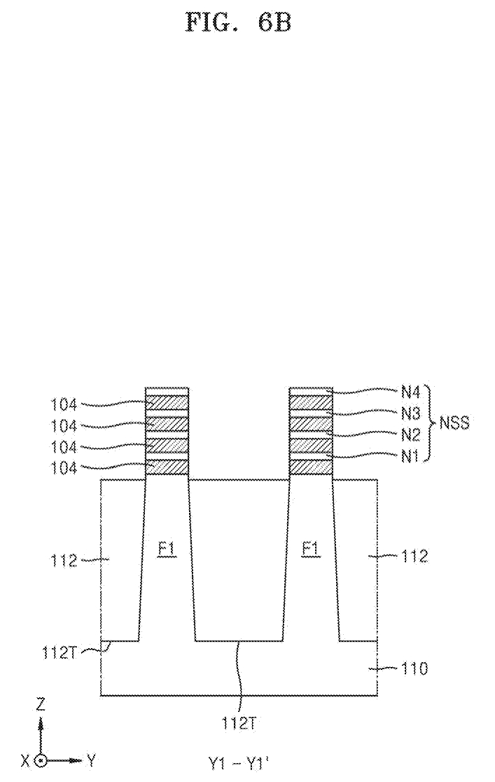

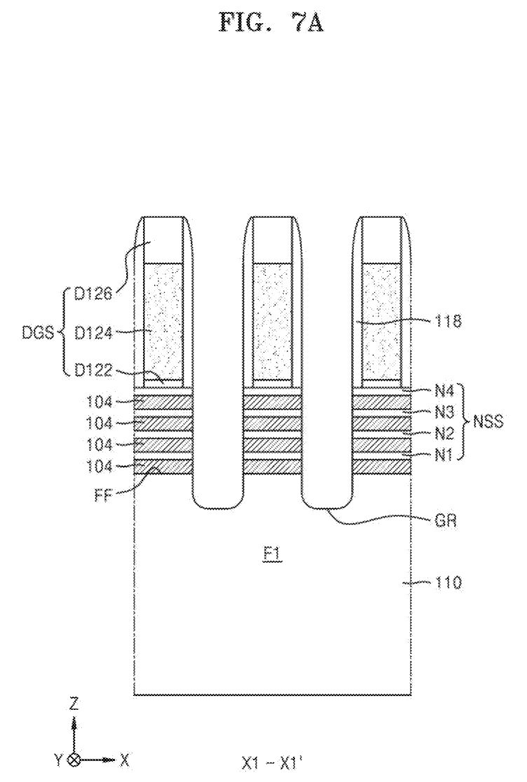

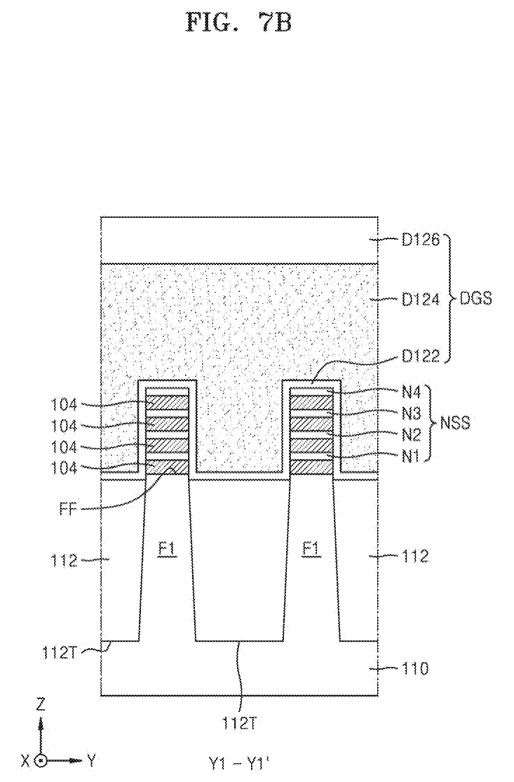

Referring to FIGS. 6A and 6B, in the result of FIG. 5, a portion of each of the plurality of sacrificial semiconductor layers 104, the plurality of semiconductor layers NS, and the substrate 110 may be etched to form a plurality of fin-type active regions F1 including the remaining portions of the substrate 110. A plurality of device isolation trenches 112T may be defined in the substrate 110 by the plurality of fin-type active regions F1. A portion of the plurality of sacrificial semiconductor layers 104 and a portion of the plurality of semiconductor layers NS may remain on a fin upper surface FF (see FIGS. 7A and 7B) of each of the plurality of fin-type active regions F1.

Thereafter, a device isolation layer 112 filling the plurality of device isolation trenches 112T may be formed. The device isolation layer 112 may include an oxide layer, a nitride layer, or a combination thereof. The portion of the plurality of sacrificial semiconductor layers 104 and the portion of the plurality of semiconductor layers NS remaining on the fin upper surface FF of each of the plurality of fin-type active regions F1 may protrude upward from the upper surface of the device isolation layer 112.

Referring to FIGS. 7A and 7B, a plurality of dummy gate structures DGS may be formed on the result of FIGS. 6A and 6B. Each of the plurality of dummy gate structures DGS may be formed to extend in the second horizontal direction (the Y direction). Each of the plurality of dummy gate structures DGS may include a dummy oxide layer D122, a dummy gate layer D124, and a dummy capping layer D126 sequentially stacked on the stacked structure including the plurality of sacrificial semiconductor layers 104 and the plurality of semiconductor layers NS. In an embodiment, the dummy gate layer D124 may include polysilicon, and the dummy capping layer D126 may include an SiN layer.

Thereafter, a plurality of insulating spacers 118 each covering both sidewalls of each of the plurality of dummy gate structures DGS may be formed. The plurality of insulating spacers 118 may include Si₃N₄, SiO₂, SiOC, SiOCN, SiCN, silicon boronitride (SiBN), SiON, silicon boron carbonitride (SiBCN), silicon oxyfluoride (SiOF), carbon-doped hydrogenated silicon oxide (SiOCH), or a combination thereof.

The plurality of dummy gate structures DGS and the plurality of insulating spacers 118 may be used as an etching mask to etch portions of the plurality of sacrificial semiconductor layers 104 and the plurality of semiconductor layers NS and portions of the plurality of fin-type active regions F1, thereby dividing the plurality of semiconductor layers NS into the plurality of nanosheet stacks NSS each including first to fourth nanosheets N1, N2, N3, and N4 and forming a plurality of grooves GR on the plurality of fin-type active regions F1. Each of the first to fourth nanosheets N1, N2, N3, and N4 may have a width in the first horizontal direction (the X direction), which is limited by the plurality of grooves GR. To form the plurality of grooves GR, dry etching, wet etching, or a combination thereof may be used.

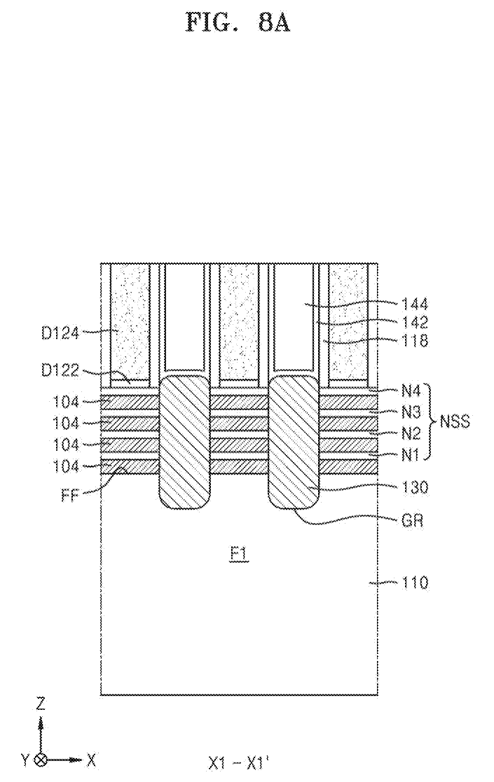

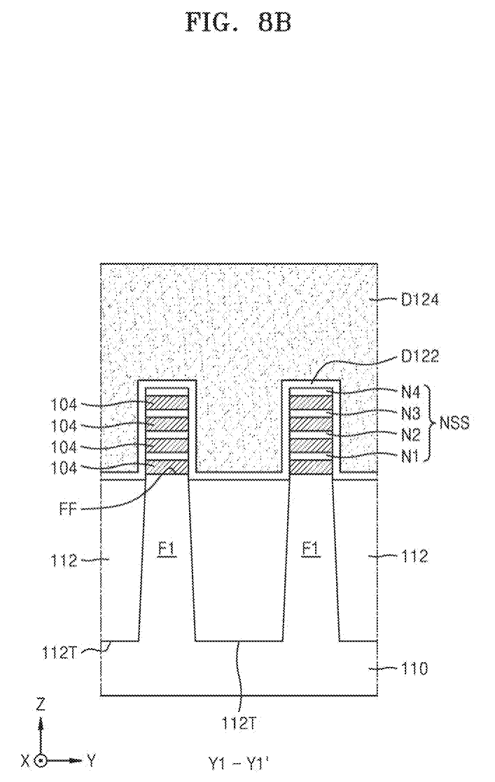

Referring to FIGS. 8A and 8B, the source/drain region 130 may be formed by epitaxially growing a semiconductor material from respective surfaces of the fin-type active region F1, the first to fourth nanosheets N1, N2, N3, and N4, and the plurality of sacrificial semiconductor layers 104 exposed in a groove GR. Each of the plurality of source/drain regions 130 may include an epitaxially grown semiconductor layer. In an embodiment, each of the plurality of source/drain regions 130 may include an Si layer, an SiC layer, or an SiGe layer. In an embodiment, when the source/drain region 130 constitutes an NMOS transistor, the source/drain region 130 may include an SiC layer doped with an n-type dopant. The n-type dopant may be selected from among phosphorus (P), arsenic (As), and antimony (Sb). In an embodiment, when the source/drain region 130 constitutes a PMOS transistor, the source/drain region 130 may include an SiGe layer doped with a p-type dopant. The p-type dopant may be selected from among boron (B) and gallium (Ga).

Thereafter, the insulating liner 142 covering a result in which the plurality of source/drain regions 130 are formed may be formed, and the inter-gate insulating layer 144 may be formed on the insulating liner 142. The insulating liner 142 may include Si₃N₄, SiCN, SiBN, SiON, SiOCN, SiBCN, or a combination thereof, and the inter-gate insulating layer 144 may include an SiO₂ layer, but the insulating liner 142 and the inter-gate insulating layer 144 are not limited thereto.

Thereafter, a portion of each of the insulating liner 142 and the inter-gate insulating layer 144 may be etched until the upper surfaces of a plurality of dummy capping layers D126 (see FIGS. 7A and 7B) are exposed. Thereafter, the plurality of dummy capping layers D126 may be removed until the dummy gate layer D124 is exposed, and the insulating liner 142 and the inter-gate insulating layer 144 may be partially removed such that the upper surface of the inter-gate insulating layer 144 and the upper surface of the dummy gate layer D124 are at an approximately same vertical level.

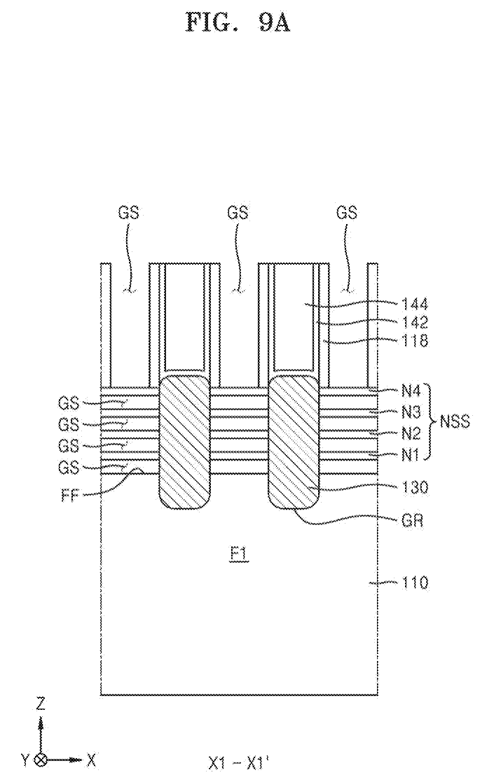

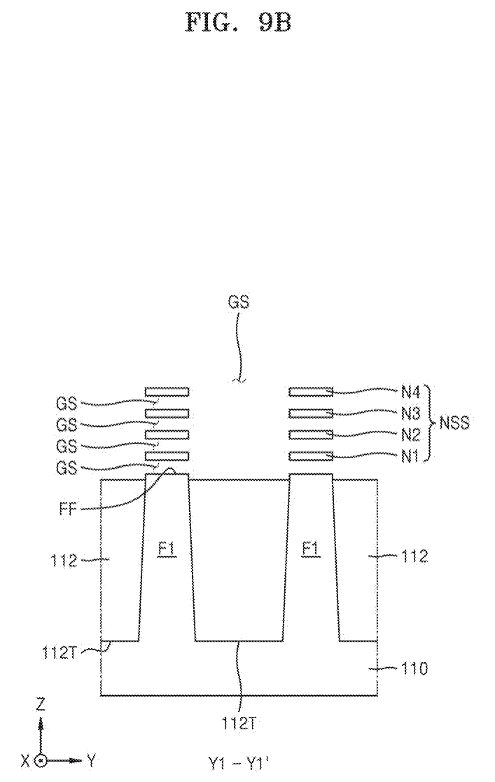

Referring to FIGS. 9A and 9B, the dummy gate layer D124 and the dummy oxide layer D122 may be removed from the result of FIGS. 8A and 8B to prepare a gate space GS. Thereafter, the plurality of sacrificial semiconductor layers 104 remaining on the fin-type active region F1 may be selectively removed through the gate space GS such that the gate space GS extends to the spaces between the first to fourth nanosheets N1, N2, N3, and N4 and the space between the fin upper surface FF of the fin-type active region F1 and the first nanosheet N1.

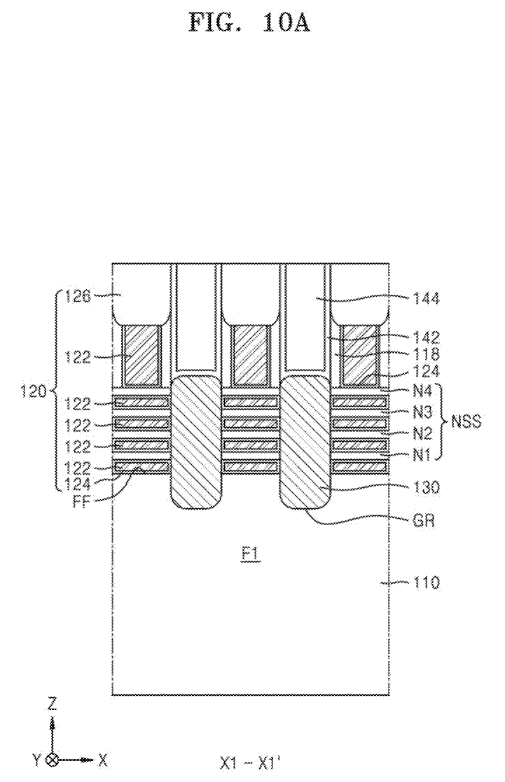

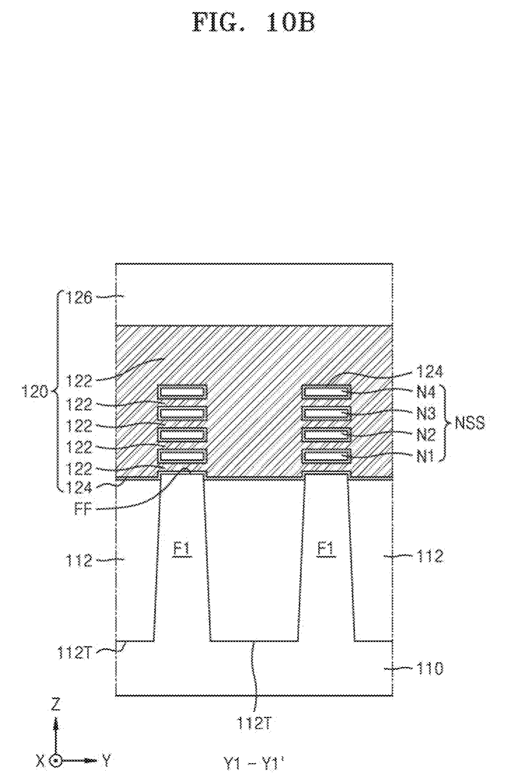

Referring to FIGS. 10A and 10B, in the result of FIGS. 9A and 9B, the gate insulating layer 124 covering the exposed surfaces of the first to fourth nanosheets N1, N2, N3, and N4 and the fin-type active region F1 may be formed. The gate insulating layer 124 may include a stacked structure of an interface dielectric layer and a high dielectric layer. The interface dielectric layer may include a low dielectric material layer having a dielectric constant of about 9 or less, e.g., an SiO₂ layer, an SiON layer, or a combination thereof. In an embodiment, the interface dielectric layer may be omitted. The high dielectric layer may include a material having a dielectric constant higher than that of the SiO₂ layer. For example, the high dielectric layer may have a dielectric constant of about 10 to about 25. The high dielectric layer may include HfO₂ but the disclosure is not limited thereto.

A plurality of gate electrodes 122 filling the gate space GS (see FIGS. 9A and 9B) may be formed on the gate insulating layer 124. Each of the plurality of gate electrodes 122 may include a metal, metal nitride, metal carbide, or a combination thereof. The metal may be selected from among Ti, W, Ru, Nb, Mo, Hf, Ni, Co, Pt, Yb, Tb, Dy, Er, and Pd. The metal nitride may be selected from among TiN and TaN. The metal carbide may be TiAlC. However, the material constituting the plurality of gate electrodes 122 is not limited thereto.

A portion of each of the gate electrode 122, the gate insulating layer 124, and the insulating spacer 118 may be removed from the upper surface of each of the gate electrode 122, the gate insulating layer 124, and the insulating spacer 118 so as to decrease the height of each of the gate electrode 122, the gate insulating layer 124, and the insulating spacer 118, and the plurality of gate capping layers 126 each covering the upper surface of each of the gate electrode 122, the gate insulating layer 124, and the insulating spacer 118 may be formed. Each of the plurality of gate capping layers 126 may include an Si₃N₄ layer.

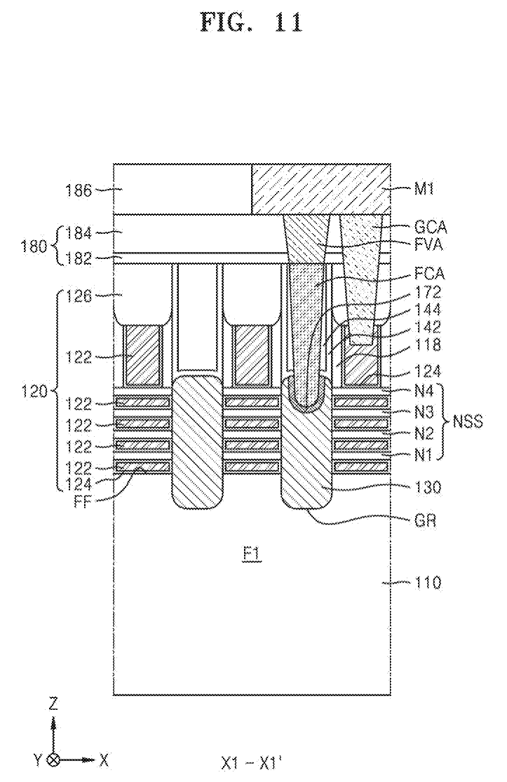

Referring to FIG. 11, in the result of FIGS. 10A and 10B, a contact hole exposing the source/drain region 130 between two adjacent gate electrodes 122 among the plurality of gate electrodes 122 may be formed, a front metal silicide layer 172 may be formed on the surface of the source/drain region 130 through the contact hole, and the front contact FCA filling the contact hole may be formed on the front metal silicide layer 172. The front metal silicide layer 172 may include a metal including Ti, W, Ru, Nb, Mo, Hf, Ni, Co, Pt, Yb, Tb, Dy, Er, or Pd. For example, the front metal silicide layer 172 may include TiSi but the disclosure is not limited thereto. In an embodiment, the front contact FCA may include only a metal plug including a single metal. In another embodiment, the front contact FCA may include the metal plug and a conductive barrier layer surrounding the metal plug. The metal plug may include Mo, W, Co, Ru, Mn, Ti, Ta, Al, Cu, a combination thereof, or an alloy thereof but the disclosure is not limited thereto. The conductive barrier layer may include a metal or conductive metal nitride. For example, the conductive barrier layer may include Ti, Ta, W, TiN, TaN, WN, WCN, TiSiN, TaSiN, WSiN, or a combination thereof but the disclosure is not limited thereto.

Thereafter, the upper insulating structure 180 may be formed by sequentially forming the upper etch-stop layer 182 and the upper insulating layer 184 covering the upper surface of each of the front contact FCA, the plurality of gate capping layers 126, and the inter-gate insulating layer 144. Thereafter, the front via contact FVA connected to the front contact FCA through the upper insulating structure 180 in the vertical direction (the Z direction) and the gate contact GCA electrically connected to the gate electrode 122 by passing through the upper insulating structure 180 and the gate capping layer 126 may be formed.

The upper etch-stop layer 182 may include SiC, SiN, SiCN, SiOC, AlN, AlON, AlO, AlOC, or a combination thereof. The upper insulating layer 184 may include an oxide layer, a nitride layer, a low dielectric layer having a dielectric constant of about 2.2 to about 2.4, or a combination thereof. For example, the upper insulating layer 184 may include a TEOS layer, an HDP oxide layer, a BPSG layer, an FCVD oxide layer, an SiON layer, an SiN layer, an SiOC layer, an SiCOH layer, or a combination thereof but the disclosure is not limited thereto.

Each of the front via contact FVA and the gate contact GCA may include a contact plug including Mo, Cu, W, Co, Ru, Mn, Ti, Ta, Al, a combination thereof, or an alloy thereof. In an embodiment, each of the front via contact FVA and the gate contact GCA may further include a conductive barrier pattern surrounding the contact plug. The conductive barrier pattern may include a metal or metal nitride. For example, the conductive barrier pattern may include Ti, Ta, W, TiN, TaN, WN, WCN, TiSiN, TaSiN, WSiN, or a combination thereof but the disclosure is not limited thereto.

Thereafter, the interlayer insulating layer 186 covering the upper insulating structure 180 and the plurality of upper wiring layers M1 passing through the interlayer insulating layer 186 may be formed. The constituent material of the interlayer insulating layer 186 may be generally the same as the constituent material of the upper insulating layer 184 described above. The upper wiring layer M1 may be connected to the front via contact FVA or the gate contact GCA. The upper wiring layer M1 may include Mo, Cu, W, Co, Ru, Mn, Ti, Ta, Al, a combination thereof, or an alloy thereof but the disclosure is not limited thereto.

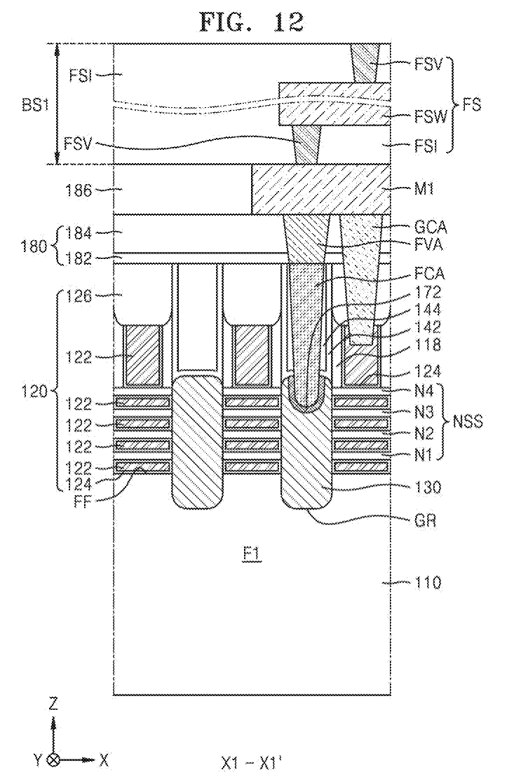

Referring to FIG. 12, the first BEOL structure BS1 may be formed on the plurality of upper wiring layers M1 and the interlayer insulating layer 186. The first BEOL structure BS1 may include the front via FSV, the front wiring layer FSW, and the front insulating layer FSI. The front via FSV and the front insulating layer FSI may constitute the front wiring structure FS.

For example, the front insulating layer FSI may include an oxide layer, a nitride layer, a low dielectric layer having a dielectric constant of about 2.2 to about 2.4, or a combination thereof. The front wiring layer FSW may be electrically connected to the front contact FCA and the front via contact FVA. The front via FSV may be electrically connected to the front wiring layer FSW, and the sidewalls of the front wiring layer FSW and the front via FSV may be surrounded by the front insulating layer FSI.

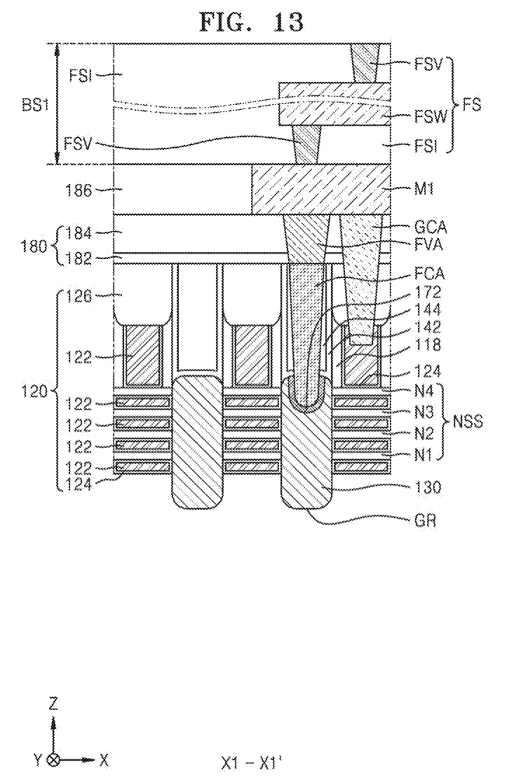

Referring to FIG. 13, a portion of the substrate 110 may be removed to decrease the height of the substrate 110 (see FIG. 12) in the vertical direction (the Z direction). In an embodiment, a grinding process may be performed until the bottom surface of the device isolation layer 112 (see FIG. 10B) is exposed.

In an embodiment, a carrier substrate may be attached to the front wiring structure FS, the substrate 110 may be upside down such that the bottom surface of the substrate 110 faces upward, and the grinding process may be performed on the substrate 110. In FIGS. 13 to 19, for convenience of drawing, the carrier substrate is omitted, and the results of FIGS. 13 to 19 are shown without being upside down.

Thereafter, the substrate 110 may be removed. In an embodiment, a process of removing the substrate 110 may include a wet etching process and/or a recess process. In the wet etching process and/or the recess process, the device isolation layer 112 may remain without being removed.

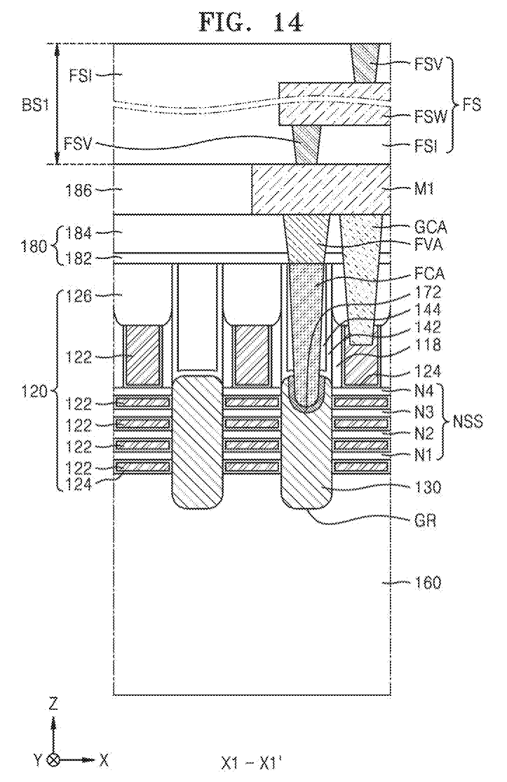

Referring to FIG. 14, the intermediate insulating layer 160 may be formed at the position where the substrate 110 has been removed. The intermediate insulating layer 160 may include SiO₂, Si₃N₄, SiON, a low dielectric material, or the like. For example, the intermediate insulating layer 160 may include a low dielectric insulating layer including at least one of carbon-containing SiO₂, carbon-containing SiON, carbon-containing Si₃N₄, and/or SiBCN.

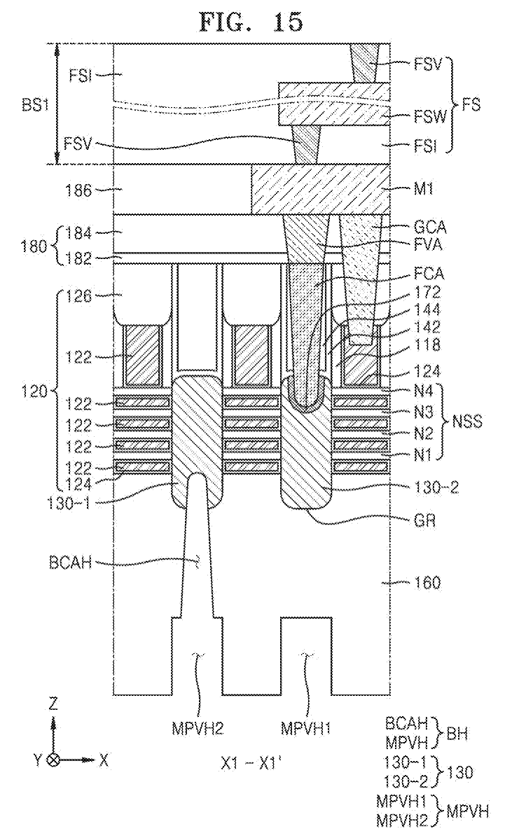

Referring to FIG. 15, a mask pattern may be formed on the lower surface of the intermediate insulating layer 160 and used as an etching mask to partially remove the intermediate insulating layer 160 and the device isolation layer 112 (see FIG. 10B), thereby forming a back hole BH. For example, the mask pattern may include a spin-on hard mask, a dielectric hard mask, and/or a dielectric metal hard mask.

The back hole BH may be formed to overlap at least a portion of the source/drain region 130 in the vertical direction (the Z direction). The back hole BH may expose the at least a portion of the source/drain region 130. The back hole BH may be a region in which the back contact BCA and the power via MPV are to be formed in the future. The back hole BH may include a back contact hole BCAH in which the back contact BCA is to be formed in the future and a power via hole MPVH in which the power via MPV is to be formed in the future. The power via hole MPVH may include a first power via hole MPVH1 in which the first power via MPV1 is to be formed in the future and a second power via hole MPVH2 in which the second power via MPV2 is to be formed in the future.

In an embodiment, the back hole BH may be formed by a plurality of etching processes. A first etching process may be a process of etching a region in which the power via MPV is to be formed in the future, and a second etching process may be a process of etching a region in which the back contact BCA is to be formed in the future.

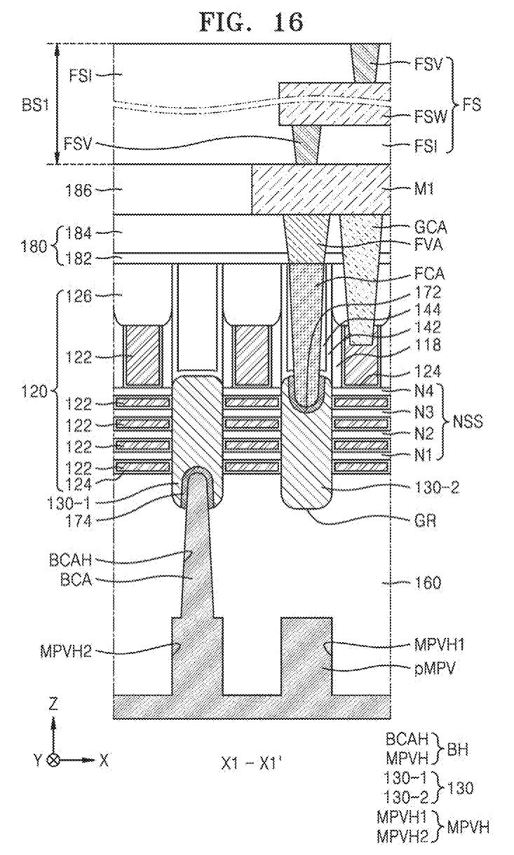

Referring to FIG. 16, the back metal silicide layer 174 may be formed on the surface of the source/drain region 130 through the back contact hole BCAH. The constituent material of the back metal silicide layer 174 is the same as the constituent material of the front metal silicide layer 172 described above. Thereafter, the back contact BCA and a preliminary power via pMPV may be formed by filling a conductive material inside the back hole BH and on the lower surface of the intermediate insulating layer 160. The back contact BCA may be connected to the source/drain region 130 through the back metal silicide layer 174. In the specification, the back contact BCA may be referred to as a contact structure. The constituent material of each of the back contact BCA and the preliminary power via pMPV is the same as the constituent material of the front contact FCA described above.

Although it is described with reference to FIG. 16 that the back contact BCA and the power via MPV are formed in the same process, the present disclosure is not limited thereto. For example, the back contact BCA and the power via MPV may be formed in different processes.

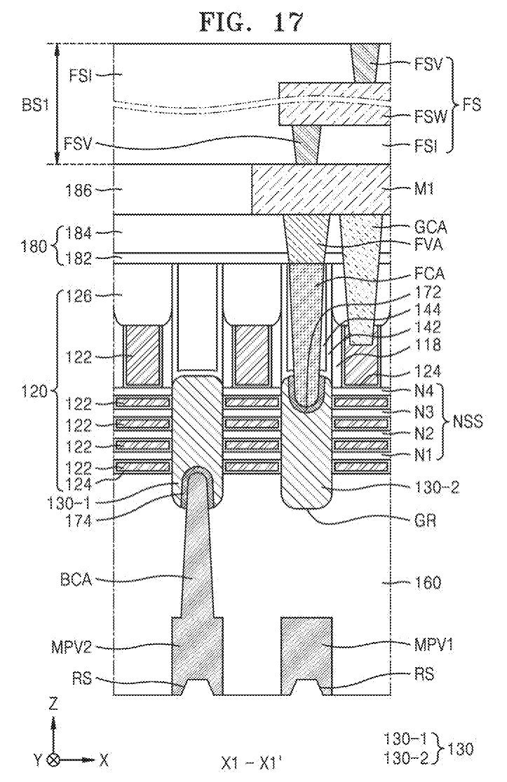

Referring to FIG. 17, at least portion of the preliminary power via pMPV (see FIG. 16) may be removed to form the power via MPV. The preliminary power via pMPV may be removed by a chemical mechanical polishing (CMP) process. In another embodiment, the preliminary power via pMPV may be removed by a dry etching process, a wet etching process, and/or a laser ablation process.

In a process of removing the at least a portion of the preliminary power via pMPV, the recess RS may be formed in the power via MPV. As descried above, the first horizontal width HW1 that is the horizontal width of the recess RS may be about 5 nm to about 20 nm, and the vertical depth D of the recess RS may be about 5 nm to about 20 nm.

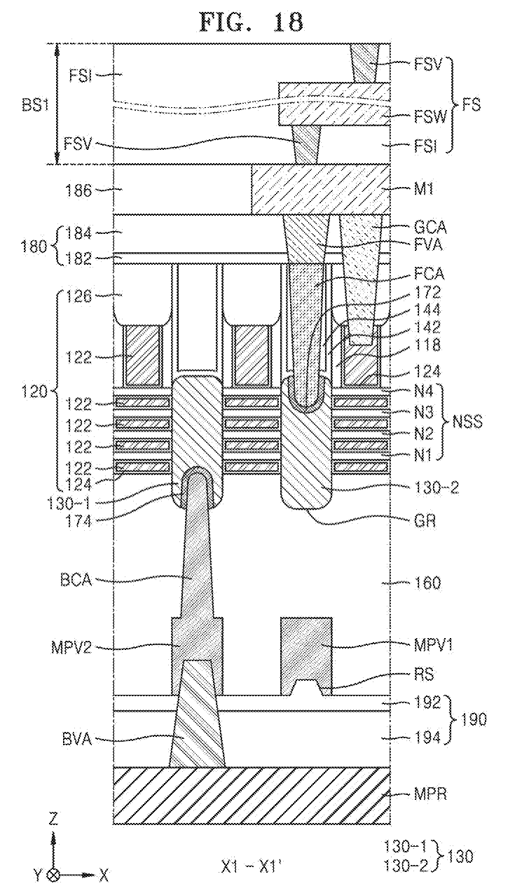

Referring to FIG. 18, the lower insulating structure 190 may be formed by sequentially forming the lower etch-stop layer 192 and the lower insulating layer 194 covering the lower surface of each of the power via MPV and the intermediate insulating layer 160. Thereafter, the back via contact BVA connected to the power via MPV through (e.g., a portion of) the lower insulating structure 190 in the vertical direction (the Z direction) may be formed. The respective constituent materials of the lower etch-stop layer 192 and the lower insulating layer 194 may be the same as the respective constituent materials of the upper etch-stop layer 182 and the upper insulating layer 184 described above. At least a portion of the back via contact BVA may be formed inside the power via MPV. In an embodiment, the at least a portion of the back via contact BVA may be formed inside the power via MPV through the recess RS of the power via MPV.

The upper surface of the back via contact BVA may be formed to be at a vertical level higher than that of the upper surface of the recess RS of the first power via MPV1. In an embodiment, the power via MPV overlapping the back via contact BVA in the vertical direction (the Z direction) may not include the recess RS by the back via contact BVA.

As described above, in an embodiment, the power via MPV and the back via contact BVA may include different materials. In another embodiment, the power via MPV and the back via contact BVA may include the same material.

Thereafter, the back power rail MPR passing through the lower insulating layer 194 may be formed. The back power rail MPR may be electrically connected to the back via contact BVA. The constituent material of the back via contact BVA may be generally the same as the constituent material of the plurality of upper wiring layers M1 described above.

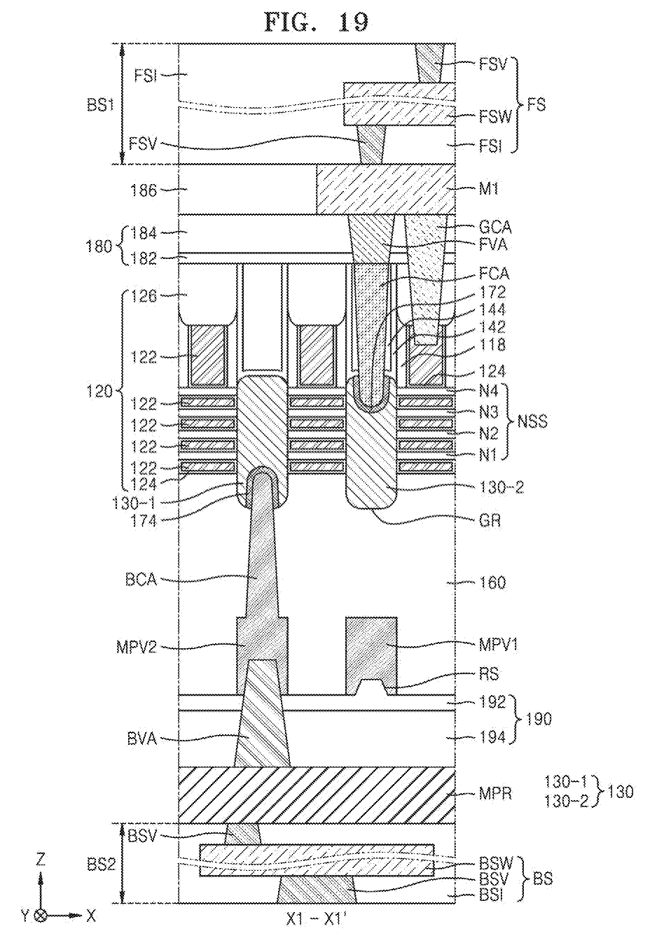

Referring to FIG. 19, the second BEOL structure BS2 may be formed on the back power rail MPR. The second BEOL structure BS2 may include the back via BSV, the back wiring layer BSW, and the back insulating layer BSI. The back via BSV and the back insulating layer BSI may constitute the back wiring structure BS.

For example, the back insulating layer BSI may include an oxide layer, a nitride layer, a low dielectric layer having a dielectric constant of about 2.2 to about 2.4, or a combination thereof. The back wiring layer BSW may be electrically connected to the back contact BCA and the back via contact BVA. The back via BSV may be electrically connected to the back wiring layer BSW, and the sidewalls of the back wiring layer BSW and the back via BSV may be surrounded by the back insulating layer BSI.

According to the method of manufacturing the integrated circuit device 100, which has been described with reference to FIGS. 5 to 19, as described above with reference to FIGS. 1 to 3, the recess RS may be formed when the power via MPV is formed by removing at least a portion of the preliminary power via pMPV. Therefore, the contact area between the power via MPV and the back via contact BVA may increase, thereby decreasing an electrical resistance. That is, the electrical characteristics of the integrated circuit device 100 may be improved.

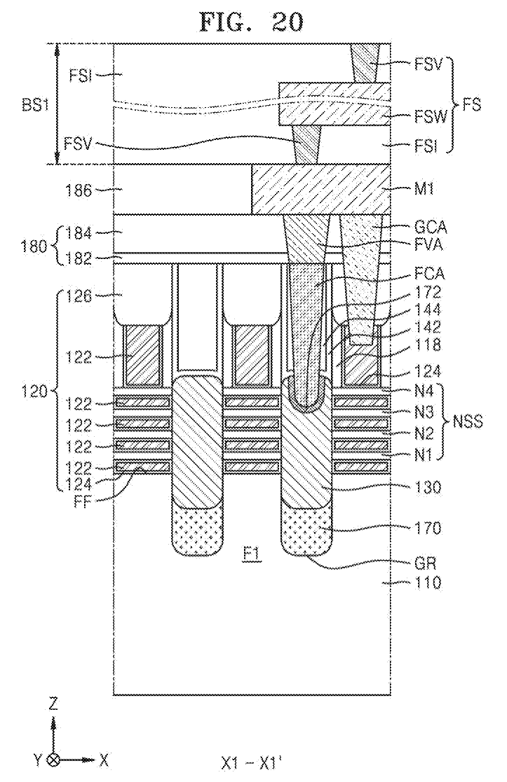

FIGS. 20 to 24 are cross-sectional views illustrating, in a process order, a method of manufacturing the integrated circuit device 100a shown in FIG. 4, wherein FIGS. 20 to 24 are cross-sectional views illustrating, in a process order, a cross-sectional structure of a portion corresponding to the cross-section taken along the line X1-X1' of FIG. 1. In FIGS. 20 to 24, like reference numerals that are the same as in FIG. 4 denote like members, and thus, a detailed description thereof is omitted herein.

Referring to FIG. 20, in the result of FIGS. 7A and 7B, the placeholder 170 may be formed in each of the grooves GR of the substrate 110, which is formed at both sides of a dummy gate structure DGS, and the source/drain region 130 may be formed on the placeholder 170. Thereafter, the dummy gate structure DGS may be removed, and the gate structure 120 may be formed at a position from which the dummy gate structure DGS has been removed.

Thereafter, the upper insulating structure 180, the front contact FCA, the front via contact FVA, the gate contact GCA, the interlayer insulating layer 186, the upper wiring layer M1, and the front wiring structure FS may be formed on the gate structure 120.

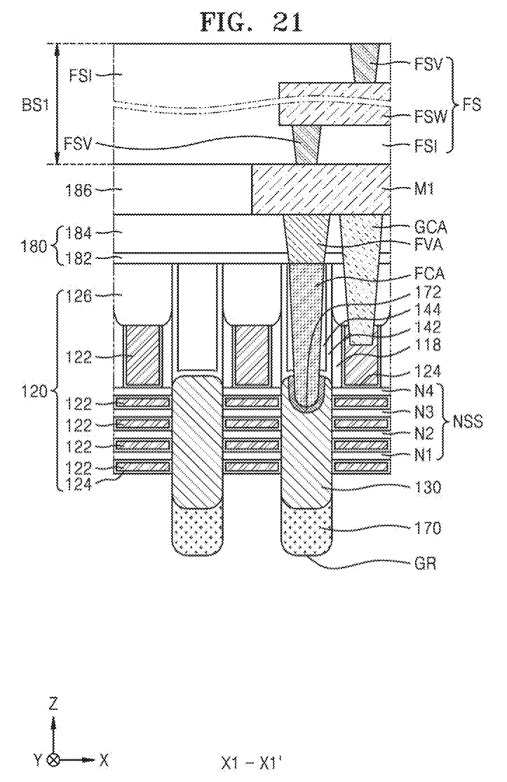

Referring to FIG. 21, the substrate 110 (see FIG. 20) may be removed from the back surface of the substrate 110. In this case, the device isolation layer 112 (see FIG. 7B) and the placeholder 170 may remain without being removed. A process of removing the substrate 110 may be the same as described above with reference to FIG. 13.

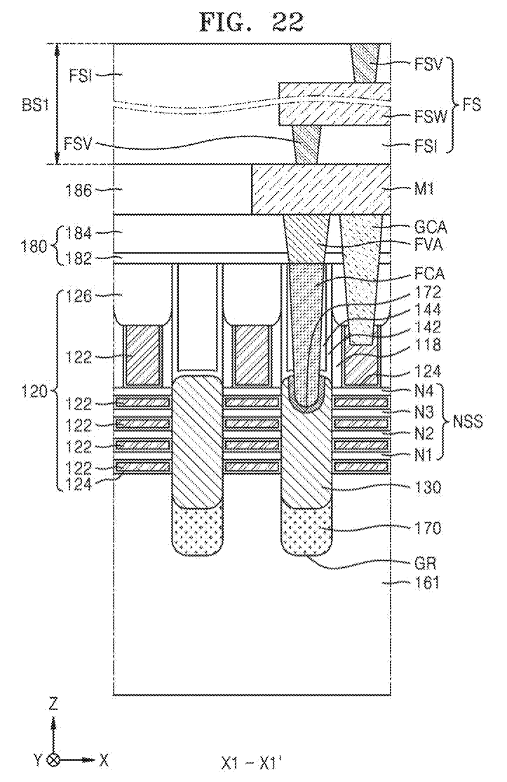

Referring to FIG. 22, the first intermediate insulating layer 161 covering and protecting the device isolation layer 112 (see FIG. 7B) and the placeholder 170 may be formed. The first intermediate insulating layer 161 may include SiO₂, Si₃N₄, SiON, a low dielectric material, or the like. For example, the first intermediate insulating layer 161 may include a low dielectric insulating layer including at least one of carbon-containing SiO₂, carbon-containing SiON, carbon-containing Si₃N₄, and/or SiBCN.

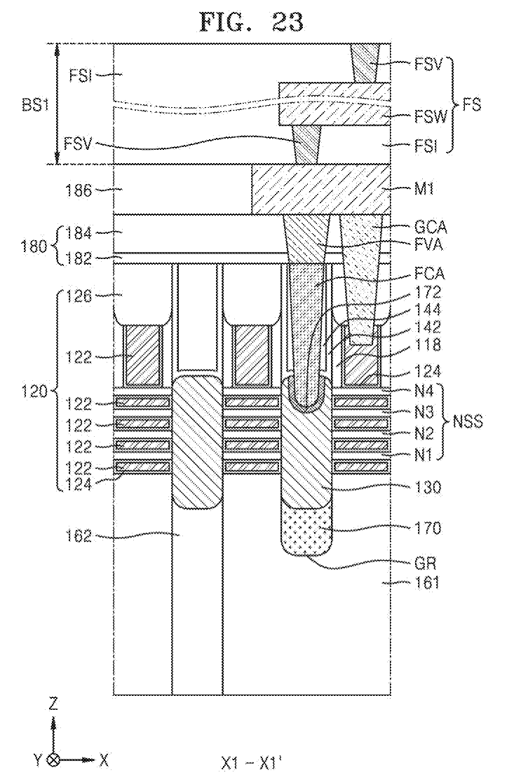

Referring to FIG. 23, a portion of the first intermediate insulating layer 161 may be removed, the placeholder 170 at a position where the back contact BCA is to be formed in the future may be removed, and the second intermediate insulating layer 162 may be formed in a region in which the first intermediate insulating layer 161 and the placeholder 170 have been removed. The second intermediate insulating layer 162 may cover the bottom surface of the source/drain region 130. The constituent material of the second intermediate insulating layer 162 may be generally the same as the constituent material of the first intermediate insulating layer 161 described above.

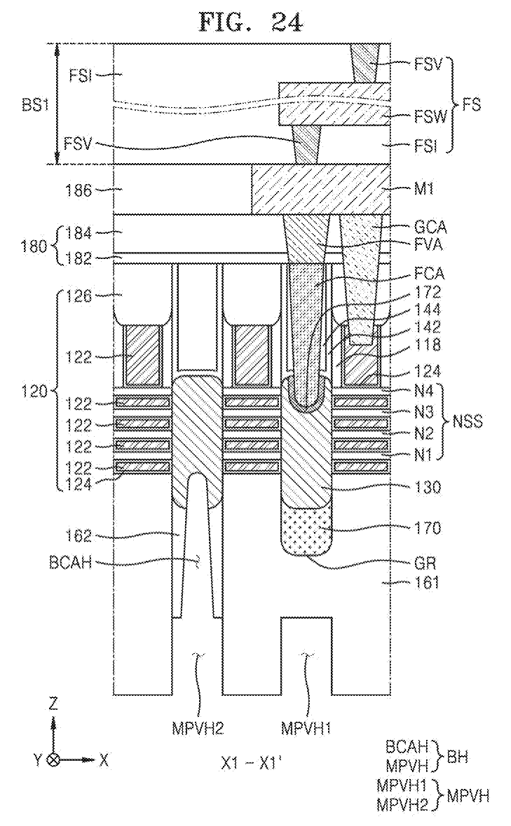

Referring to FIG. 24, the back hole BH may be formed by removing at least a portion of each of the first intermediate insulating layer 161 and the second intermediate insulating layer 162. A method of forming the back hole BH may be the same as described above with reference to FIG. 15. The power via hole MPVH may be formed on the first intermediate insulating layer 161, and the back contact hole BCAH and the power via hole MPVH may be formed on the second intermediate insulating layer 162.

As described above, the power via hole MPVH may include the first power via hole MPVH1 in which the first power via MPV1 is to be formed in the future and the second power via hole MPVH2 in which the second power via MPV2 is to be formed in the future. The first power via hole MPVH1 may be formed on the first intermediate insulating layer 161, and the second power via hole MPVH2 may be formed on the second intermediate insulating layer 162.

Thereafter, as described with reference to FIGS. 16 to 19, the back hole BH may be filled with a conductive material, and the lower insulating structure 190, the back via contact BVA, the back power rail MPR, and the second BEOL structure BS2 may be formed to form the integrated circuit device 100a of FIG. 4.

While the present disclosure has been particularly shown and described with reference to embodiments thereof, it will be understood that various changes in form and details may be made therein without departing from the spirit and scope of the following claims.

What is claimed is:

1. An integrated circuit device comprising:
a cell transistor comprising:
a nanosheet stack comprising a plurality of nanosheets spaced apart from each other in a vertical direction;
a gate electrode on the nanosheet stack and extending in a horizontal direction; and
a first source/drain region connected to the nanosheet stack;
a back contact beneath the cell transistor and connected to the first source/drain region;
a first power via at a vertical level lower than that of the back contact;
a front wiring structure on and connected to the cell transistor; and
a back wiring structure beneath the first power via and connected to the cell transistor,
wherein the back wiring structure is connected to the first power via and the back contact, and
wherein a lower surface of the first power via does not overlap the back contact in the vertical direction and comprises a recess.

2. The integrated circuit device of claim 1, wherein the lower surface of the first power via has a concave shape.

3. The integrated circuit device of claim 1, further comprising a plurality of power vias including the first power via and connected to the back contact,
wherein the plurality of power vias are at a same vertical level, and
wherein, in a plan view, the plurality of power vias have a shape of lines spaced apart from each other.

4. The integrated circuit device of claim 1, wherein a vertical depth of the recess is about 5 nm to about 20 nm.

5. The integrated circuit device of claim 1, wherein a horizontal width of the recess is about 5 nm to about 20 nm.

6. The integrated circuit device of claim 1, further comprising:
a second source/drain region; and
a placeholder on a bottom surface of the second source/drain region.

7. The integrated circuit device of claim 6, wherein the placeholder overlaps the first power via in the vertical direction.

8. An integrated circuit device comprising:
a plurality of cell transistors comprising:
a plurality of nanosheet stacks each comprising a plurality of nanosheets spaced apart from each other in a vertical direction;
a plurality of gate electrodes respectively on the plurality of nanosheet stacks and extending in a horizontal direction; and
a plurality of source/drain regions each between gate electrodes from among the plurality of gate electrodes and connected to one or more of the plurality of nanosheet stacks;
a plurality of back contacts beneath the plurality of cell transistors and connected to the plurality of source/drain regions;
a plurality of power vias at a vertical level lower than that of the plurality of back contacts and connected to the plurality of back contacts;
a plurality of back via contacts at a vertical level lower than that of the plurality of power vias and connected to the plurality of power vias;
a front wiring structure on and connected to the plurality of cell transistors; and
a back wiring structure on lower surfaces of the plurality of power vias and connected to the plurality of cell transistors,
wherein the back wiring structure is connected to the plurality of back contacts, the plurality of power vias, and the plurality of back via contacts, and
wherein a lower surface of a first power via not overlapping the plurality of back contacts in the vertical direction, among the plurality of power vias, comprises a recess.

9. The integrated circuit device of claim 8, wherein upper surfaces of the plurality of back via contacts are at a vertical level higher than a vertical level of the recess.

10. The integrated circuit device of claim 8, further comprising an insulating structure on lower surfaces of the plurality of power vias and comprising an etch-stop layer and an insulating layer,
wherein the plurality of back via contacts pass through at least a portion of the insulating structure in the vertical direction.

11. The integrated circuit device of claim 8, further comprising an intermediate insulating layer on lower surfaces of the plurality of cell transistors,
wherein the plurality of back contacts and the plurality of power vias pass through at least a portion of the intermediate insulating layer in the vertical direction.

12. The integrated circuit device of claim 8, wherein the plurality of back contacts are connected to a first source/drain region among the plurality of source/drain regions, and
wherein the first power via does not overlap the first source/drain region in the vertical direction.

13. The integrated circuit device of claim 8, wherein the plurality of power vias comprise a same material as that of the plurality of back via contacts.

14. The integrated circuit device of claim 8, wherein the plurality of power vias comprise a material different from that of the plurality of back via contacts.

15. The integrated circuit device of claim 8, wherein the plurality of power vias comprises a second power via at a vertical level that is the same as a vertical level of the first power via,
wherein the second power via overlaps a first back contact, among the plurality of back contacts, in the vertical direction, and is integrally formed with the first back contact.

16. The integrated circuit device of claim 8, further comprising a placeholder on a bottom surface of a second source/drain region among the plurality of source/drain regions,
wherein the first power via and the placeholder are surrounded by a first intermediate insulating layer, and
wherein the plurality of back contacts are surrounded by a second intermediate insulating layer.

17. An integrated circuit device comprising:
a plurality of cell transistors comprising:
a plurality of nanosheet stacks each comprising a plurality of nanosheets spaced apart from each other in a vertical direction;
a plurality of gate electrodes respectively on the plurality of nanosheet stacks and extending in a horizontal direction; and
a plurality of source/drain regions each between gate electrodes from among the plurality of gate electrodes and connected to one or more of the plurality of nanosheet stacks;
an intermediate insulating layer beneath the plurality of cell transistors;
a plurality of back contacts below the plurality of cell transistors and connected to a first source/drain region among the plurality of source/drain regions by passing through at least a portion of the intermediate insulating layer;
a plurality of power vias connected to the plurality of back contacts and passing through at least a portion of the intermediate insulating layer at a vertical level lower than a vertical level of the plurality of back contacts;
a plurality of back via contacts at a vertical level lower than that of the plurality of power vias and connected to the plurality of power vias;
a plurality of front contacts on the plurality of cell transistors and connected to a second source/drain region among the plurality of source/drain regions;
a plurality of gate contacts on the plurality of cell transistors and connected to the plurality of gate electrodes;
a front wiring structure on an upper surface of each of the plurality of front contacts and the plurality of gate contacts, and connected to the plurality of cell transistors; and
a back wiring structure on lower surfaces of the plurality of power vias and connected to the plurality of cell transistors,
wherein the front wiring structure is connected to the plurality of front contacts and the plurality of gate contacts,
wherein the back wiring structure is connected to the plurality of power vias and the plurality of back via contacts, and
wherein a lower surface of a first power via not overlapping the plurality of back contacts in the vertical direction, among the plurality of power vias, comprises a recess.

18. The integrated circuit device of claim 17, wherein the recess has a tapered shape having a horizontal width decreasing toward the plurality of cell transistors on a vertical cross-section.

19. The integrated circuit device of claim 17, wherein, at a same vertical level, a horizontal width of each of the plurality of back via contacts is greater than a horizontal width of the recess of the first power via.

20. The integrated circuit device of claim 17, wherein a vertical depth of the recess is about 5 nm to about 20 nm, and a horizontal width of the recess is about 5 nm to about 20 nm.
